(19) United States
(12) Patent Application Publication
(10) Pub. No.: US 2025/0046569 A1
(43) Pub. Date: Feb. 6, 2025

(54) INSPECTION DEVICE AND FILM QUALITY INSPECTION METHOD

(71) Applicant: Hitachi High-Tech Corporation, Minato-ku, Tokyo (JP)

(72) Inventors: Yasuhiro SHIRASAKI, Tokyo (JP); Minami UCHIHO, Tokyo (JP); Kazufumi YACHI, Tokyo (JP)

(21) Appl. No.: 18/722,800

(22) PCT Filed: Jan. 28, 2022
(86) PCT No.: PCT/JP2022/003391

§ 371 Date: Jun. 21, 2024

(51) Int. Cl. H01J 37/22; G01N 23/225; H01J 37/10

(52) U.S. Cl. CPC H01J 37/226; G01N 23/225; H01J 37/10; H01J 37/224

(57) ABSTRACT

Film quality of a deposited semiconductor film, insulating film, or the like is inspected in a non-contact manner. An inspection device 1 for inspecting film quality of a film formed on a sample 16 includes a charged particle source 12 configured to irradiate the sample with a charged particle beam 13, a first light source 21 configured to irradiate the sample with first light 26, a photodetection system configured to detect signal light 28 generated when the sample is irradiated with the first light, a charge control electrode 17 configured to control an electric field on the sample or a second light source 22 configured to irradiate the sample with second light 27, a control device 30 configured to modulate an electronic state of the sample using the charged particle source and the charge control electrode or the second light source, and a computer 31 configured to estimate the film quality of the film formed on the sample based on a detection signal of the signal light modulated according to the modulated electronic state of the sample, the detection signal being output from the photodetection system.

### TECHNICAL FIELD

The present disclosure relates to an inspection device and a film quality inspection method using the same.

### BACKGROUND ART

PTL 1 discloses a SEM equipped with ultraviolet light for discharge. It is known that charge on an insulating film can be removed by irradiation with the ultraviolet light. PTL 2 discloses a SEM equipped with a charge control electrode that controls an electric field on a sample. It is known that a charge amount of the sample charged by electron beam irradiation can be controlled by controlling a voltage of the charge control electrode.

### CITATION LIST

### Patent Literature

PTL 1: JP2000-357483A
PTL 2: JP2006-338881A

### Non Patent Literature

NPL 1: D. E. Aspnes, “Third-Derivative Modulation Spectroscopy with Low-Field Electroreflectance” Surface Science 37 (1973) 418-442

### SUMMARY OF INVENTION

### Technical Problem

In a semiconductor device, a film quality of a semiconductor film or an insulating film is important. For example, performance of a transistor greatly depends on properties of a gate insulating film and properties of an interface between the gate insulating film and a layer in contact therewith. If there is a defect in the insulating film or the interface, charge accumulates in the defect due to application of an electric field when driving the device, which adversely affects a device operation. In order to inspect the film quality such as the defect that becomes a problem during the device operation, it is effective to apply an electric field to the film to be inspected in the same manner as during the device operation and measure a change in characteristics thereof.

After the device is completed, the film quality can be inspected by electrical characteristic inspection in which the device is actually operated. However, the post-completion inspection cannot prevent defects from occurring during a mass production process. In development of a semiconductor manufacturing process, a film quality can be measured under application of an electric field by manufacturing electrodes that sandwich a film to be inspected and applying a voltage between the electrodes, but manufacturing the electrodes for this purpose is time-consuming and costly.

Accordingly, in the mass production process of the semiconductor device or in the development of the semiconductor manufacturing process, it is desired to inspect the film quality of the deposited semiconductor film, insulating film, or the like in a non-contact manner. Here, the film quality refers to material characteristics that the film exhibits depending on charge, a strain, a defect, a state of a base, a state of an interface, or the like of the deposited material. The film to be inspected in the invention includes a wide range of films formed in the manufacturing process of the semiconductor device, regardless of a manufacturing method and a material of the film. This also applies to, for example, a film obtained by performing processing such as annealing after deposition, a film (thermal oxide film) obtained by thermally oxidizing a semiconductor substrate, and a film formed by ion implantation on a semiconductor substrate. The material includes both an inorganic material and an organic material.

### Solution to Problem

According to an aspect of the invention, there is provided an inspection device for inspecting a film quality of a film formed on a sample, and the inspection device includes: a charged particle source configured to irradiate the sample with a charged particle beam; a first light source configured to irradiate the sample with first light; a photodetection system configured to detect signal light generated when the sample is irradiated with the first light; a charge control electrode configured to control an electric field on the sample or a second light source configured to irradiate the sample with second light; a control device configured to modulate an electronic state of the sample using the charged particle source and the charge control electrode or the second light source; and a computer configured to estimate the film quality of the film formed on the sample based on a detection signal of the signal light modulated according to the modulated electronic state of the sample, the detection signal being output from the photodetection system.

According to another aspect of the invention, there is provided a film quality inspection method for inspecting a film quality of a film formed on a sample, and the film quality inspection method includes: irradiating the sample with a charged particle beam to charge the sample; irradiating the sample with probe light in a state in which an electronic state of the sample is modulated; detecting signal light generated when the sample is irradiated with the probe light; and estimating the film quality of the film formed on the sample based on a detection signal of the signal light modulated according to the modulated electronic state of the sample.

### Advantageous Effects of Invention

The film quality of the deposited semiconductor, insulating film, or the like can be inspected in a non-contact manner. Other problems and novel features will become apparent from description of the present specification and the accompanying drawings.

### BRIEF DESCRIPTION OF DRAWINGS

FIG. 1 is a schematic configuration diagram of an inspection device according to Embodiment 1.

FIG. 2A is an example of a control sequence for controlling an electronic state of a sample.

FIG. 2B is an example of the control sequence for controlling the electronic state of the sample.

FIG. 2C is an example of the control sequence for controlling the electronic state of the sample.

FIG. 3A is an example of a detection signal spectrum.

FIG. 3B is an example of the detection signal spectrum.

FIG. 4 is a data structure example of a database for estimating a film quality.

FIG. 5 is a control flow for inspection of the film quality that can be estimated based on electric field dependency of the detection signal.

FIG. 6 is a diagram showing changes in an intensity of the detection signal when a voltage applied to a charge control electrode is swept.

FIG. 7 is a data structure example of a database for estimating the film quality obtained from electric field dependency of a detection signal.

FIG. 8 is a display example of a result of the film quality inspection.

FIG. 9A is an example of a setting-measurement screen (setting tab).

FIG. 9B is an example of the setting-measurement screen (measurement tab).

FIG. 9C is an example of a result output screen.

FIG. 10A is a schematic configuration diagram of an inspection device according to Modification 1.

FIG. 10B is a diagram showing a relationship between a signal electron detection amount and an energy filter voltage.

FIG. 11 is a schematic configuration diagram of an inspection device according to Modification 2.

FIG. 12 is a schematic configuration diagram of an inspection device according to Embodiment 2.

FIG. 13 is a schematic configuration diagram of an inspection device according to Embodiment 3.

FIG. 14 is a schematic configuration diagram of an inspection device according to Embodiment 4.

### DESCRIPTION OF EMBODIMENTS

Hereinafter, embodiments of the invention will be described. The drawings shown in the present embodiment show specific examples of the invention, and these are provided for understanding the invention, and are not to be used for limitedly interpreting the invention.

In an inspection device according to the present embodiment, a film quality is evaluated by optical inspection. That is, as specific examples will be described later, material characteristics of a film are detected as optical characteristics of the film, and information on the film quality is obtained from the detected optical characteristics. In the present embodiment, in the optical inspection, an electronic state of a sample to be inspected is modulated and controlled by controlling charge on the film to be inspected and/or controlling an internal electric field by light irradiation.

In the following embodiments, a purpose of controlling an electric field intensity on the film to be inspected is roughly divided into two. The first is to optimize conditions for the optical inspection. For example, by executing the optical inspection under the electric field intensity at which a maximum signal light intensity is obtained, the inspection can be executed at a high SNR, and a throughput of the inspection can be improved. The second is to inspect the film quality depending on the electric field. As for the material characteristics depending on the electric field intensity, information on the film quality can be obtained by changing the applied electric field intensity and detecting a change in a detection signal. Details will be described later.

Hereinafter, an embodiment will be disclosed in which an object to be inspected is an insulating film formed on a semiconductor wafer and an interface thereof, but application of the present technology is not limited thereto. Film quality measurement under an electric field is also effective in, for example, a semiconductor film, an organic film, or an interface thereof.

### Embodiment 1

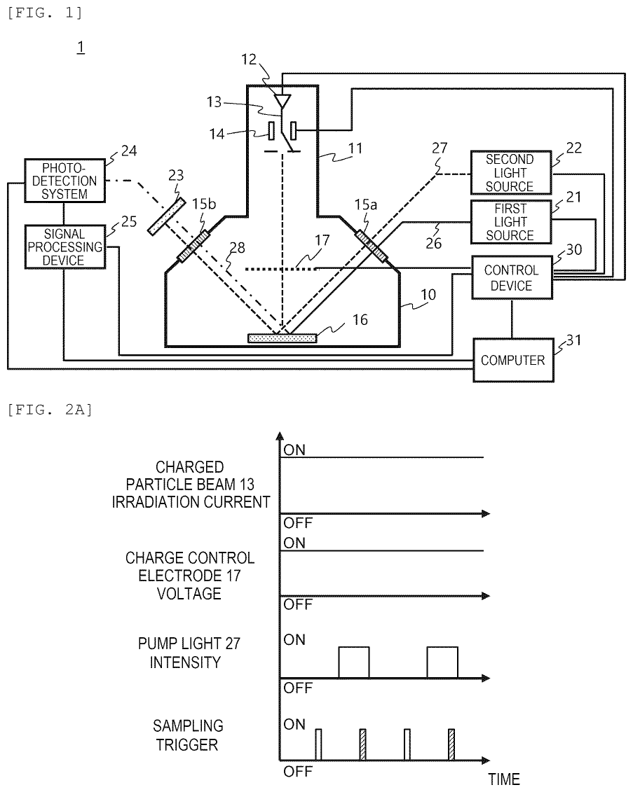

FIG. 1 shows a schematic configuration of an inspection device 1 according to Embodiment 1. The inspection device 1 includes, as a main configuration, a charged particle beam device that controls an electronic state of a sample to be inspected among samples, a light irradiation system that irradiates the sample with probe light, a photodetection system that detects signal light generated by irradiating the sample with the probe light, and a control system that controls these.

### (Charged Particle Beam Device)

The charged particle beam device includes a sample chamber 10 and a lens barrel 11, the inside of which is maintained in a vacuum atmosphere by an exhaust mechanism (not shown). A sample 16 such as a semiconductor wafer is accommodated in the sample chamber 10. The lens barrel 11 accommodates a charged particle source 12 that generates a charged particle beam 13 to irradiate the sample 16, and a blanker 14 that chops the charged particle source 12. Here, an electron gun, a flood gun, an ion source, or the like can be used as the charged particle source 12 as long as the charged particle source 12 can generate the charged particle beam 13 for charging the sample 16. A charged particle optical component such as a lens or a deflector constituting a charged particle optical system that guides the charged particle beam 13 to the sample 16 may be provided.

A charge control electrode 17 that controls a charge amount of the sample 16 by controlling an electric field on the sample 16 is provided in the vicinity of the sample 16. The electric field immediately above the sample 16 is controlled by applying a voltage to the charge control electrode 17. A charged state of the sample 16 is controlled by the electric field applied to the charge control electrode 17 moving secondary charged particles generated when the sample 16 is irradiated with the charged particle beam 13 away from or back to the sample 16. The charge control electrode 17 is disposed at a position about several to 30 mm away from the sample 16, for example. For this reason, it is desirable to use an electrode plate having a metal mesh or holes so as not to interfere with irradiating the sample 16 with the charged particle beam 13, or probe light 26 or pump light 27 to be described later.

Further, charge on the sample 16 can be quickly removed by using ultraviolet light as disclosed in PTL 1. On the other hand, in a case of light having a longer wavelength than the ultraviolet light, it is known that the electric field (interface electric field) inside the sample can be controlled without changing the charged state. Therefore, in a configuration example in FIG. 1, a second light source 22 that irradiates the sample 16 with light (referred to as pump light (second light) 27) is provided. The electronic state of the sample to be inspected can be controlled by irradiating the sample with the pump light 27, and a content of the electronic state to be controlled can be changed by selecting a wavelength of the pump light 27. Specifically, it is possible to discharge the sample and control an interface electric field by using ultraviolet light, and it is possible to control the interface electric field by using light having a longer wavelength than the ultraviolet light. The second light source 22 can be configured in the same manner as a first light source 21 to be described later.

### (Light Irradiation System)

The inspection device 1 includes the first light source 21 that irradiates the sample 16 with probe light (first light) 26 in order to execute optical inspection on a film to be inspected formed on the sample 16. A white light source such as a xenon lamp, a laser, an LED, or the like can be used as the first light source 21. The white light source can also be used monochromatically through a monochromator. Although not shown, the light irradiation system includes optical components such as a lens or a mirror constituting an optical system that guides the probe light 26 to the sample 16, and a polarizer that controls polarization of the probe light 26.

In the example in FIG. 1, the first light source 21 is disposed outside the sample chamber 10, and the probe light 26 is introduced into the sample chamber 10 via a viewport 15a provided in the sample chamber 10. In this example, the pump light 27 is also introduced into the sample chamber 10 via the viewport 15a, but the probe light 26 and the pump light 27 may be introduced into the sample chamber 10 from different viewports.

### (Photodetection System)

Signal light 28 is generated by irradiating the sample 16 with the probe light 26. The signal light 28 includes reflected light, scattered light (including Raman scattered light), emitted light, and diffracted light. The photodetection system detects the signal light 28, and includes an optical filter 23, a photodetection system 24, and a signal processing device 25. The optical filter 23 is a filter that removes light other than the signal light 28, and the photodetection system 24 detects the signal light 28 by receiving light transmitted through a viewport 15b via the optical filter 23. A power meter, a photodiode, a spectrometer, or the like can be used as the photodetection system 24 according to the signal light 28 to be detected. The signal processing device 25 processes a detection signal from the photodetection system obtained under an electric field condition inside the plurality of samples. The signal processing device 25 is, for example, a lock-in amplifier, and extracts a modulation intensity, a phase, and the like of the detection signal from the photodetection system 24.

The signal light 28 detected by the photodetection system 24 is determined according to a film quality that is inspected for the film to be inspected. For example, information such as an interface electric field, a defect, and a strain can be obtained by detecting the reflected light, information such as a vibration level, a stress, and a strain can be obtained by detecting the scattered light (including the Raman scattered light), information such as a defect and a light emission efficiency can be obtained by detecting the emitted light, and information such as structural periodicity and a refractive index can be obtained by detecting the diffracted light.

### (Control System)

The control device 30 controls components of the inspection device 1. The control device 30 controls operations of the charged particle beam device, the light irradiation system, and the photodetection system based on inspection conditions input from a computer 31, for example. The control device 30 is implemented by a program executed by a processor such as a CPU. For example, a field-programmable gate array (FPGA) or an application specific integrated circuit (ASIC) may be used.

The computer 31 sets conditions for inspection and measurement by the inspection device 1 and estimates the film quality based on the detection signal from the photodetection system. The computer 31 stores various databases and conversion formulas necessary for setting the conditions and estimating the film quality.

Setting the conditions for inspection and measurement includes setting parameters as follows. These parameters are set by a user through a GUI of the computer 31. Conditions for the charged particle beam 13 that charges the sample include an acceleration voltage, a current amount, an irradiation area, an irradiation position, an irradiation cycle by a blanker, and the like. Conditions for the charge control electrode 17 that controls the charge amount of the sample include a voltage value, an application cycle thereof, and the like. Conditions for the pump light 27 for controlling discharge or an internal electric field of the sample include a wavelength, an intensity, polarization, an irradiation cycle, and the like. Conditions for the probe light 26 include a wavelength, an intensity, polarization, and the like. Conditions for a detector of the photodetection system 24 include a gain and the like.

Functions of the control device 30 may be executed by the computer 31.

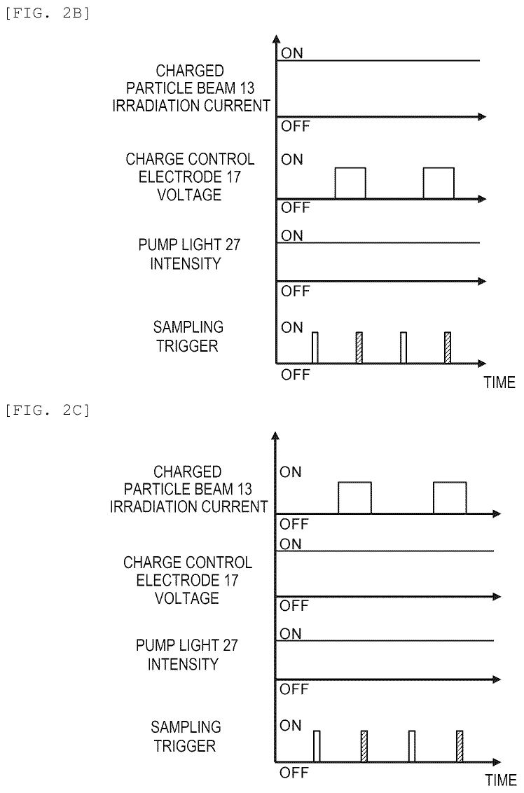

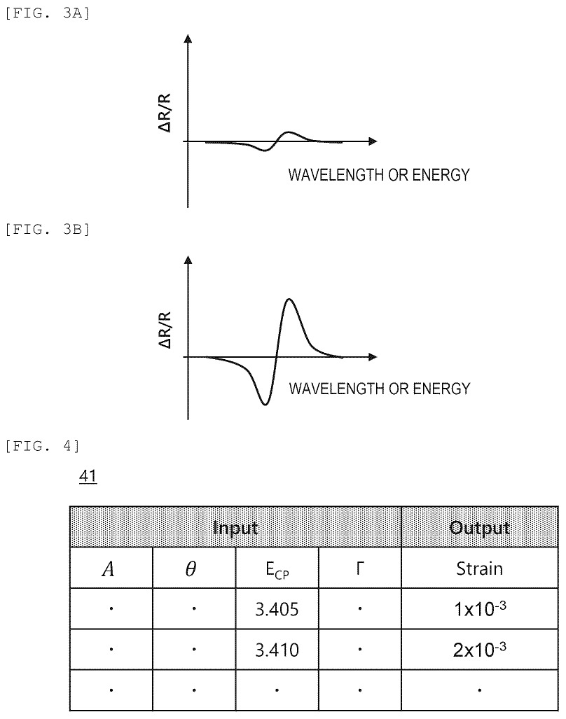

FIGS. 2A to 2C show examples of a control sequence for modulating the electronic state of the sample. Each example is a control sequence in which the electronic state of the sample 16 is controlled by three action sources of the charged particle beam 13, the charge control electrode 17, and the pump light 27. In FIG. 2A, the conditions for the charged particle beam 13 and the charge control electrode 17 are fixed, and the conditions for the pump light 27 are modulated. A parameter to be modulated may be a wavelength or polarization, but an intensity is used here. When the intensity of the pump light 27 is ON, charge on the sample 16 is to be removed or the electric field inside the sample is to be controlled depending on the wavelength of the pump light 27. In FIG. 2B, the conditions for the charged particle beam 13 and the pump light 27 are fixed, and the conditions for the charge control electrode 17 are modulated. In FIG. 2C, the conditions for the charge control electrode 17 and the pump light 27 are fixed, and the conditions for the charged particle beam 13 are modulated. In order to modulate the electronic state of the sample 16, some parameters may be modulated for at least one of the three action sources. When modulating a plurality of action sources, modulation patterns for the plurality of action sources may be the same or different. When the pump light 27 has a short wavelength and is used for a purpose of discharging the film to be inspected, and it is only necessary to control whether the sample is charged, the charge control electrode 17 may be omitted. As in the control sequences in FIGS. 2B and 2C, when the charge amount of the sample is modulated by the charged particle beam 13 and the charge control electrode 17, the second light source 22 can be omitted. However, even in such a case, when it is desired to control the electric field (interface electric field) inside the sample, it is effective to provide the second light source 22 capable of emitting light having a longer wavelength than the ultraviolet light, and when it is desired to reset the charge amount of the sample for each modulation, it is effective to provide the second light source 22 capable of emitting the ultraviolet light.

Sampling of the detection signal output from the photodetection system by detecting the signal light 28 is performed according to a sampling trigger. The sampling trigger is synchronized with the modulation of the electronic state of the sample. Accordingly, it is possible to obtain an intensity SA of the signal light 28 when the modulated action source is in a first state (the intensity of the pump light 27 is OFF in the example in FIG. 2A) and an intensity SB of the signal light 28 when the modulated action source is in a second state (the intensity of the pump light 27 is ON in the example in FIG. 2A), and it is possible to obtain information on the film quality of the film to be inspected by comparing the intensity SA with the intensity SB. Although the control sequences in FIGS. 2A to 2C each create two types of electronic states, namely the first state and the second state, three or more types of electronic states may be created by modulating the plurality of action sources with different modulation patterns.

Here, the sampling trigger has various aspects depending on a configuration of the photodetection system, and is not limited to a specific aspect. For example, the second light source 22 modulates the pump light 27 in synchronization with a synchronization signal from the control device and 30, the photodetection system continuously outputs the detection signal from the signal processing device 25. In this case, the computer 31 can receive the synchronization signal from the control device 30 and sample the detection signal from signal processing device 25 using the sampling trigger synchronized with the synchronization signal. Alternatively, in the photodetection system, the photodetection system 24 may continuously output the detection signal, and the signal processing device 25 may execute signal processing by receiving the synchronization signal from the control device 30 and sampling the detection signal from the photodetection system 24 using the sampling trigger synchronized with the synchronization signal. Further, in the photodetection system, the photodetection system 24 may receive the synchronization signal from the control device 30 and detect the signal light 28 using the sampling trigger synchronized with the synchronization signal. This configuration may be adopted when the detector of the photodetection system 24 is a spectrometer.

The signal processing by the signal processing device 25 in the photodetection system will be described. For example, the detector of the photodetection system 24 is a power meter and the signal light 28 is reflected light of the probe light 26. Assuming that the control sequence in FIG. 2A is applied, the signal intensity SA of the signal light 28 in the first state and the signal intensity SB of the signal light 28 in the second state are defined. The signal processing device 25 normalizes a difference between signal intensities acquired in the two electronic states and outputs the normalized difference as the detection signal. In this case, the detection signal is expressed as (Math. 1), which means a rate of change in reflectance.

$$\begin{matrix}[ Math . 1 ] & \\ \frac{Δ R}{R} = \frac{{S}_{B} - {S}_{A}}{{S}_{A}} & ( 1 )\end{matrix}$$

When a lock-in amplifier is used as the signal processing device 25, an amplitude ΔR₀ and a phase θ are output, and in this case, the detection signal is expressed as (Math. 2).

$$\begin{matrix}[ Math . 2 ] & \\ \frac{Δ R}{R} = Δ {R}_{0} {e}^{i θ} & ( 2 )\end{matrix}$$

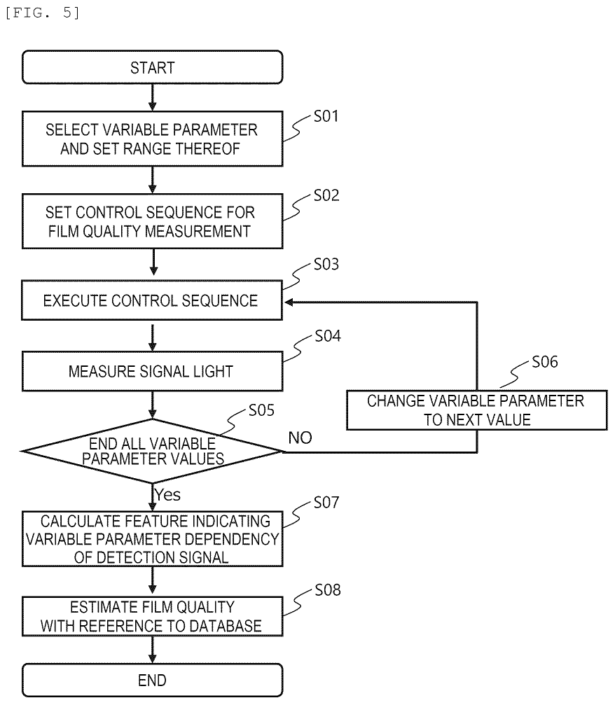

When a detection signal ΔR/R is detected while changing the wavelength of the probe light 26, a spectrum as shown in FIG. 3A or FIG. 3B is obtained. A horizontal axis represents the wavelength or energy of the reflected light. Here, FIG. 3A shows a case where the voltage of the charge control electrode 17 is set to 0 V, and FIG. 3B shows a case where the voltage of the charge control electrode 17 is set to +3 V. By adjusting the voltage of the charge control electrode 17, that is, the charge amount of the sample 16, the detection signal having a higher SNR is obtained. A similar spectrum can also be obtained using a white light source for the probe light 26 and a spectrometer as the detector of the photodetection system 24.

As shown in FIG. 3A or FIG. 3B, the computer 31 estimates the film quality such as a strain and a dopant concentration of the semiconductor at an interface between the insulating film and the semiconductor based on an intensity and a shape of the detection signal spectrum. The obtained detection signal spectrum has a relationship expressed as (Math. 3), for example (NPL 1).

$$\begin{matrix}[ Math . 3 ] & \\ \frac{Δ R}{R} ( E ) = R e [ A {{e}^{i θ} ( E - {E}_{C P} + i Γ )}^{- n} ] & ( 3 )\end{matrix}$$

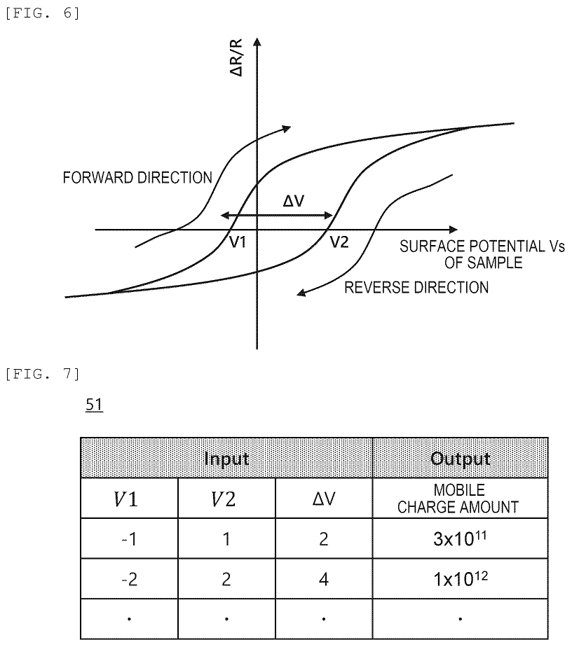

In (Math. 3), A is an intensity, θ is a phase, E is energy, E_{CP} is critical point energy, Γ is a broadening factor, and n is a coefficient depending on the material of the film to be inspected. (Math. 3) is fitted to the obtained detection signal spectrum. Fit parameters (A, θ, E_{CP}, Γ) included in (Math. 3) are obtained by fitting. On the other hand, the computer 31 stores, as a database, film quality information on various combinations of fit parameters. FIG. 4 shows an example of the database.

FIG. 4 is a data structure example of a database 41 for estimating the film quality. A strain of the film corresponding to a combination of fit parameters (A, θ, E_{CP}, Γ) is registered in the database 41. The computer 31 estimates the strain of the film to be inspected by collating a fit parameter obtained by (Math. 3) with the database 41. The film quality information may be registered as a function having the fit parameter as an argument in the database 41, and a registration form thereof is not limited. In this example, a model formula such as (Math. 3) and the database 41 are used when measuring the strain using the signal light 28 as the reflected light of the probe light 26, and for example, when the signal light 28 is the scattered light or the emitted light, or when a measurement target is other than the strain, a model formula or a database corresponding thereto may be used.

The computer 31 stores, as a database, a relationship between the parameter obtained from the detection signal in this way and the film quality, and estimates the film quality information based on the parameter detected from the signal light 28. The computer 31 includes a database corresponding to the detection signal from the photodetection system and an analysis formula used for film quality inspection executed by the inspection device 1, and estimates the film quality using the database corresponding to the inspection to be executed.

Next, a control flow when the film quality is obtained from electric field dependency of the detection signal will be described. The film quality such as a defect or a mobile charge amount can be estimated based on how the detection signal changes (electric field dependency of the detection signal) when the electric field applied to the sample is changed. FIG. 5 shows the control flow for the inspection of the film quality that can be estimated based on the electric field dependency of the detection signal. An example in which the control sequence in FIG. 2A is applied to estimate the mobile charge amount of the film to be inspected will be described.

First, a variable parameter is selected and a range there of is set (S01). Here, the variable parameter is a voltage applied to the charge control electrode 17. Subsequently, a control sequence for film quality measurement is set. As described above, the control sequence in FIG. 2A is set (S02). The control sequence is executed and the signal light 28 is measured while changing the variable parameter (S03 to S06), a detection signal is obtained for the set range of the variable parameter, and then a feature indicating variable parameter dependency of the detection signal is calculated (S07). The computer 31 stores, as a database, film quality information on the feature indicating on the variable parameter dependency of the detection signal. A film quality of a film to be inspected is estimated with reference to the database (S08).

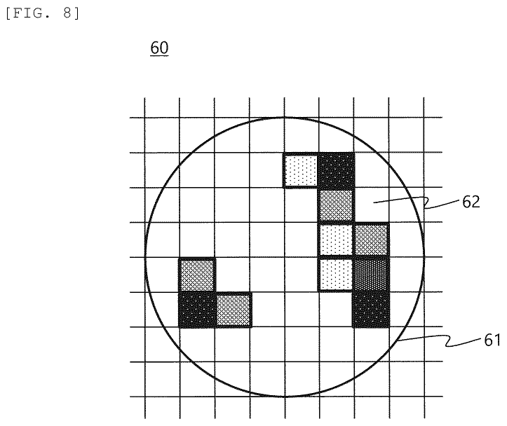

As an example of the control flow, FIG. 6 shows changes in an intensity of the detection signal (ΔR/R) when the voltage applied to the charge control electrode 17 is swept in a forward direction (from negative to positive) and a reverse direction (from positive to negative). A horizontal axis represents a surface voltage Vs of the sample 16. The surface voltage Vs has a relationship with a voltage V_{cc} applied to the charge control electrode 17 as shown in (Math. 4), and can be obtained by conversion from the applied voltage V_{cc}. (Math. 4) is obtained by simulation or the like.

$$\begin{matrix}[ Math . 4 ] & \\ {V}_{S} = f ( {V}_{CC} ) & ( 4 )\end{matrix}$$

FIG. 7 is a data structure example of a database 51 for estimating the film quality obtained from the electric field dependency of the detection signal. A mobile charge amount of a film corresponding to a combination of features (V1, V2, ΔV) indicating electric field intensity dependency of the detection signal is registered in the database 51. The computer 31 estimates the mobile charge amount of the film to be inspected by collating, with the database 51, features (here, voltages V1, V2 and hysteresis for obtaining a specific reflectance) representing the electric field intensity dependency obtained from a measurement result as shown in FIG. 6. By using the database corresponding to a target film quality, it is possible to estimate a fixed charge amount, a flat band voltage, and the film quality such as charge, a strain, a defect, and an interface state of the material as described above. The film quality information may be registered as a function having the feature as an argument in the database 51, and a registration form thereof is not limited.

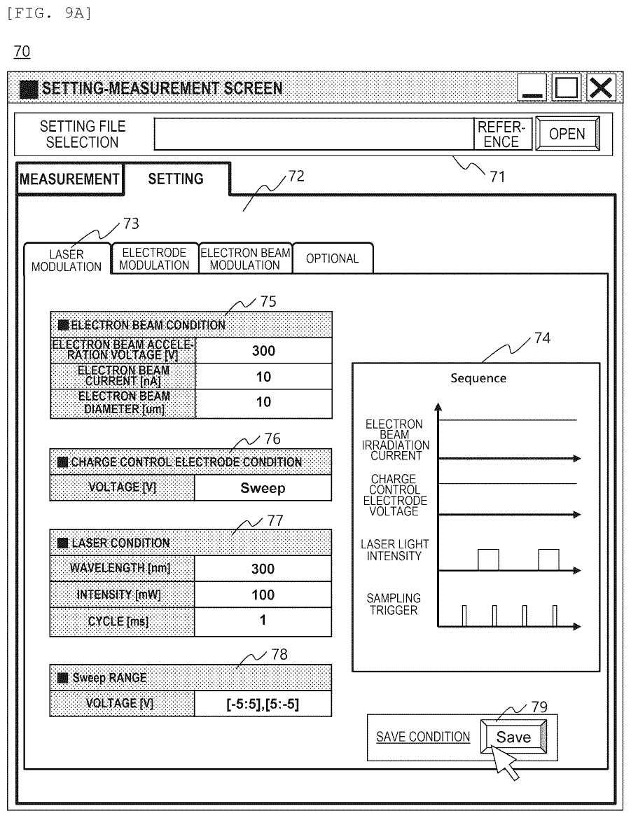

FIG. 8 shows a display example of a result of the optical inspection by the inspection device 1. The optical inspection is executed on a chip section designated by the user on the semiconductor wafer, for example. The optical inspection may be executed on all chip sections. A film quality of each chip section subjected to the optical inspection is displayed as a wafer heat map 60. In the wafer heat map 60, chip sections 62 are displayed in a wafer 61, and for example, if the inspected film quality is a defect, chip sections having a higher defect density are displayed in a darker color. Accordingly, the user can visually recognize the film quality of each chip section.

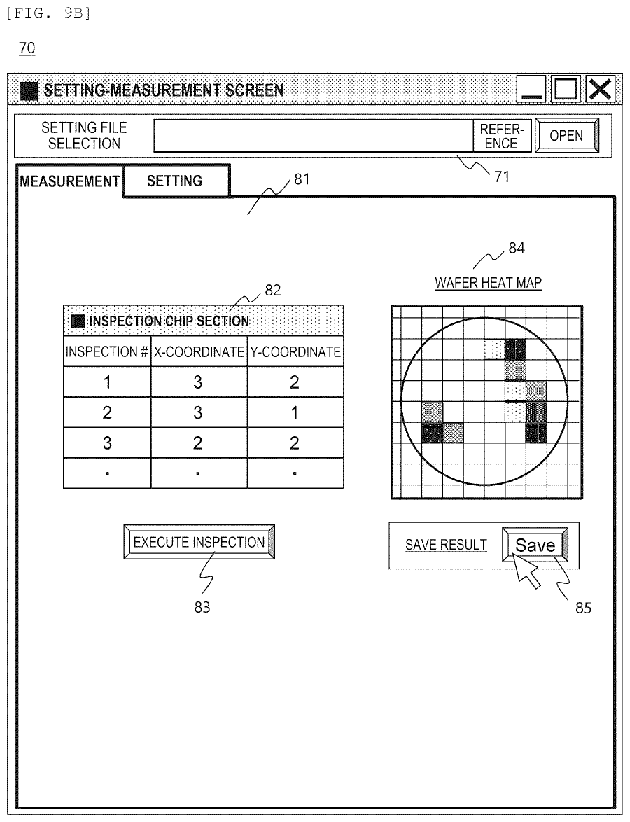

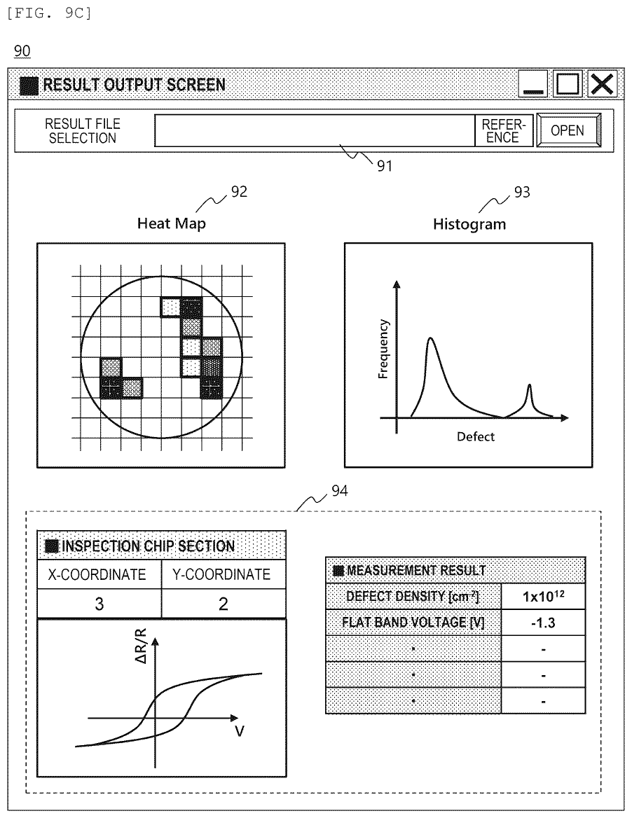

FIG. 9A shows an example of a setting-measurement screen 70 that is a graphical user interface (GUI) for performing film quality measurement by the inspection device 1 and displaying a result. The setting-measurement screen 70 includes a setting file selection section 71, and a setting file stored in the computer 31 in the past measurement can be called. For example, when different film qualities are inspected on the same wafer, a work load of the user can be reduced by utilizing the past set contents.

By selecting a control sequence tab included in a setting tab 72, the control sequences in FIGS. 2A to 2C or other control sequences can be selected. Here, a laser modulation tab 73 is selected, and in this case, a control sequence for modulating the pump light shown in FIG. 2A is selected as shown in a sequence diagram 74. In this device, an electron beam is used as a charged particle beam, and a laser light is used as pump light.

The user opens the laser modulation tab 73 and sets conditions for modulating the electronic state of the wafer by an electron beam condition setting section 75, a charge control electrode condition setting section 76, and a laser condition setting section 77. Further, in this example, in order to estimate the film quality based on the electric field dependency of the detection signal, the applied voltage is set to be swept in the charge control electrode condition setting section 76. In this case, a sweep range setting section 78 is displayed, and the user sets a range in which the applied voltage is swept. When the above setting is completed, a save button 79 is pressed to save the set contents.

When the condition setting is completed, the user opens a measurement tab 81 as shown in FIG. 9B. The user designates a chip section to be subjected to the optical inspection in an inspection chip section setting section 82 and presses an inspection execution button 83. Accordingly, the optical inspection is executed on the designated chip section under conditions set in the setting tab 72. When the optical inspection for all the designated chip sections is completed, the wafer heat map is displayed on a wafer heat map display section 84 in order to simply show an inspection result to the user. The user confirms the inspection result and presses a save button 85 to save the result of the optical inspection.

The user can confirm details of the inspection result from a result output screen 90 shown in FIG. 9C. A result data file to be displayed in detail is called from the result file selection section 91 provided on the result output screen 90. In this example, a wafer heat map display section 92 and a histogram display section 93 for displaying the same wafer heat map as the setting-measurement screen 70 are provided. A histogram displayed in the histogram display section 93 indicates an appearance frequency (the number of chip sections) of shading indicating a defect density in the wafer heat map displayed in the wafer heat map display section 92. By designating any one of the chip sections displayed in the wafer heat map display section 92, details of measurement results for the individual chip sections can be displayed. In this example, the measurement result of the detection signal in a specific chip section and the estimated film quality information are displayed in an inspection chip section measurement result display section 94.

### (Modification 1)

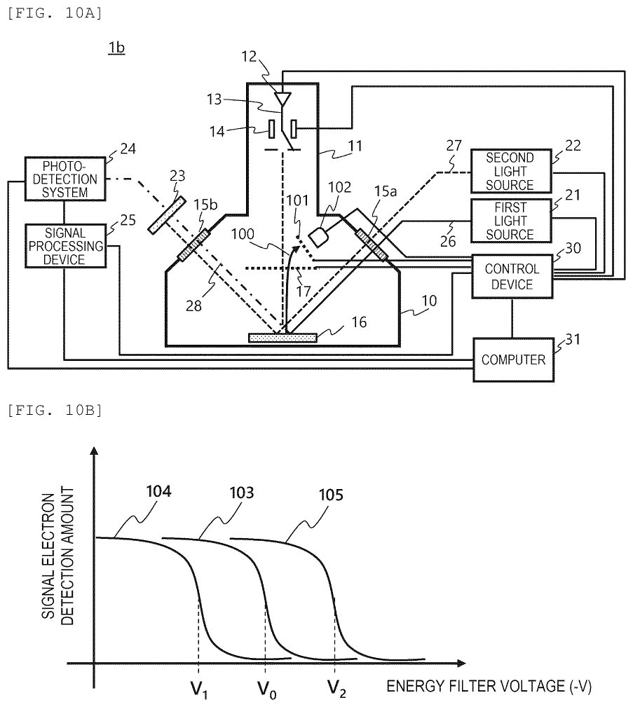

FIG. 10A shows a modification of the inspection device 1 shown in FIG. 1. In Embodiment 1, when the voltage applied to the charge control electrode 17 is swept, the sample surface voltage Vs is converted from the voltage V_{cc} applied to the charge control electrode 17 using (Math. 4), and (Math. 4) is obtained by simulation or the like. However, depending on the measurement conditions, an error may occur between a value obtained from (Math. 4) and the true sample surface voltage Vs.

An inspection device 1b in FIG. 10A includes an energy filter 101 and a signal electron detector 102 as a mechanism that actually measures the sample surface voltage Vs of the sample 16. Here, the signal electron detector 102 is a detector that detects signal electrons 100 generated when the sample 16 is irradiated with the charged particle beam 13, and the signal electrons 100 to be detected may be secondary electrons or reflected electrons (backscattered electrons). A negative voltage is applied to the energy filter 101 by the control device 30, and only signal electrons that can climb over an electric field barrier generated by the negative voltage are detected by the signal electron detector 102. That is, an amount of signal electrons detected by the signal electron detector 102 depends on the voltage of the energy filter 101. Using this feature, in the inspection device 1b, the computer 31 calculates the sample surface voltage Vs from energy of the signal electrons 100.

FIG. 10B shows a relationship between a signal electron detection amount and an energy filter voltage. A signal electron spectrum can be acquired by detecting the signal electron detection amount while changing the negative voltage applied to the energy filter 101. A shift amount depends on the sample surface voltage Vs. This is because a force for pulling the signal electrons 100 back to a sample side changes depending on the sample surface voltage Vs. Assuming that a signal electron spectrum 103 is a signal electron spectrum when the sample 16 is uncharged, signal electron spectra 104, 105 are signal electron spectra when the sample 16 is positively charged and negatively charged, respectively. Therefore, for example, when a voltage at which a differential value of the signal electron spectrum is maximum is defined as the sample surface voltage Vs, potentials when uncharged, positively charged, and negatively charged are potentials V₀, V₁, V₂, respectively. Accordingly, the sample surface voltage Vs can be actually measured without using a conversion formula of (Math. 4). The signal electron spectrum 103 can be obtained by measurement in a state in which charge on the sample 16 is removed by the pump light 27 having a short wavelength such as ultraviolet light.

In the present modification, the energy of the signal electrons 100 is discriminated using the energy filter 101, but the sample surface voltage Vs can also be measured by detecting the electron energy with a spectrometer or the like that spectrally detects the signal electrons according to the energy.

### (Modification 2)

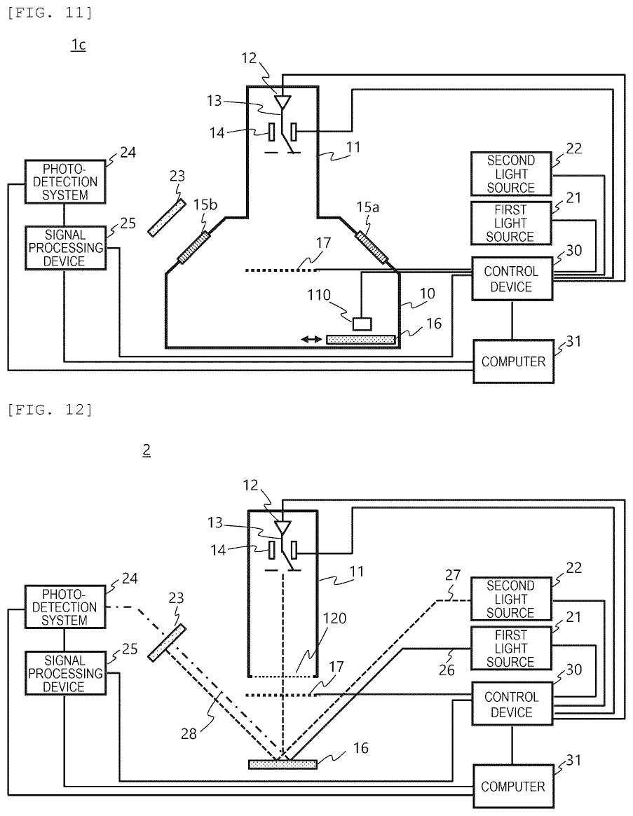

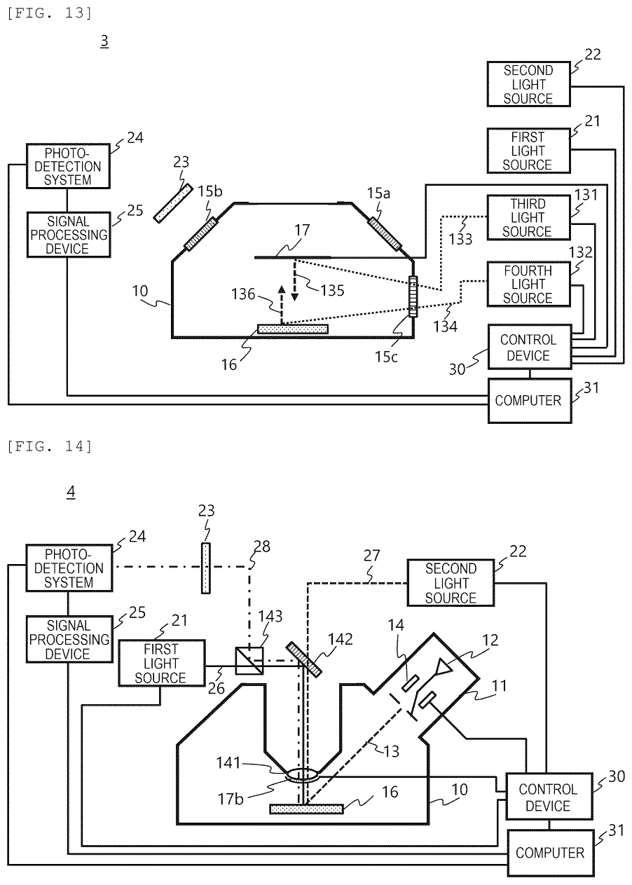

FIG. 11 shows a modification of the inspection device 1 shown in FIG. 1. Similarly to Modification 1, Modification 2 also enables actual measurement of the sample surface voltage Vs. An inspection device 1c includes a surface electrometer 110 as a mechanism that actually measures the sample surface voltage Vs of the sample 16. The sample 16 is moved to a position of the surface electrometer 110 provided in the sample chamber 10, and the sample surface voltage Vs is measured.

Hereinafter, other configuration examples of the inspection device 1 will be described as Embodiments 2 to 4. The same components as those in Embodiment 1 are denoted by the same reference numerals, and redundant description thereof will be omitted.

### Embodiment 2

In Embodiment 1, since the sample 16 is disposed in a vacuum atmosphere and vacuum pumping takes time, which reduces a throughput of inspection and measurement. Embodiment 2 is a configuration example in which the sample 16 is disposed in the atmosphere.

In a configuration of an inspection device 2 shown in FIG. 12, the charged particle source 12 is disposed inside the lens barrel 11 in a vacuum atmosphere, and the lens barrel 11 is provided with a partition wall 120 for maintaining the inside thereof in the vacuum atmosphere. The charged particle beam 13 emitted from the charged particle source 12 penetrates the partition wall 120 and is emitted to the atmosphere, and the sample 16 is irradiated with the charged particle source 12. Further, when the charged particle source 12 is an electrode that generates ions by corona discharge in the atmosphere, the lens barrel 11 and the partition wall 120 for maintaining the charged particle source in the vacuum atmosphere can also be omitted.

### Embodiment 3

In Embodiment 3, photoelectrons generated by irradiating a metal electrode with excitation light are used as charged particles. An inspection device 3 according to Embodiment 3 uses an electron beam source having a simple configuration as a charged particle beam source, and can modulate a charge amount of the sample 16 by exchanging photoelectrons generated by irradiating the sample 16 and/or the charge control electrode 17 with short-wavelength light.

A third light source 131 and a fourth light source 132 are light sources that generate light having a wavelength less than 400 nm, and outputs thereof are controlled by the control device 30. The third light source 131 and the fourth light source 132 can each be configured similarly to the first light source 21. The third light source 131 and the fourth light source 132 are disposed outside the sample chamber 10, and light from the light sources is introduced into the sample chamber 10 via a viewport 15c provided in the sample chamber 10.

The charge control electrode 17 is irradiated with first excitation light (third light) 133 from the third light source 131. First photoelectrons 135 are generated from a location irradiated with the first excitation light 133. When a potential of the charge control electrode 17 is negative compared to that of the sample 16, the first photoelectrons 135 receive a force toward the sample and the sample 16 is irradiated with the first photoelectrons 135. Accordingly, the sample 16 is negatively charged.

On the other hand, the sample 16 is irradiated with second excitation light (fourth light) 134 from the fourth light source 132. Second photoelectrons 136 are generated from a location irradiated with the second excitation light 134. When the potential of the charge control electrode 17 is positive compared to that of the sample 16, the second photoelectrons 136 receive a force toward the charge control electrode and move away from the sample 16. Accordingly, the sample 16 is positively charged.

In this way, the potential of the sample 16 can be modulated and controlled by the first photoelectrons 135 and the second photoelectrons 136 generated by the first excitation light 133 and the second excitation light 134. The third light source 131 and the fourth light source 132 may be one light source, and in this case, an optical path of the excitation light is controlled by the control device 30 such that the charge control electrode 17 or the sample 16 is irradiated with the excitation light. Alternatively, both the charge control electrode 17 and the sample 16 may be simultaneously irradiated with the excitation light. In order to avoid absorption of short-wavelength light in the atmosphere, the third light source and the fourth light source may be disposed in a vacuum.

### Embodiment 4

In the configuration of the inspection device 1 shown in FIG. 1, arrangement of the charge control electrode 17 and the charged particle source 12 interferes with the probe light (first light) 26 and the pump light (second light) 27, and the light irradiation system and the photodetection system cannot be disposed in the vicinity of the sample 16. Therefore, it is difficult to focus light on the sample, and spatial resolution of the measurement is limited. In the inspection device 4 according to Embodiment 4, an optical system such as an objective lens for probe light and signal light is disposed directly above a sample in order to obtain high spatial resolution.

In the inspection device 4, an optical lens 141 for irradiating the sample 16 with the probe light 26 and the pump light 27 is disposed directly above the sample such that an optical axis thereof is along a direction perpendicular to a film to be inspected formed on the sample. Since the probe light 26 and the pump light 27 are focused on the sample 16 by the optical lens 141, measurement can be performed with high spatial resolution. The charged particle source 12 is disposed obliquely with respect to the optical axis of the optical lens 141, and the charged particle beam 13 passes between the optical lens 141 and the sample 16 and the sample 16 is obliquely irradiated with the charged particle beam 13. Further, since a distance between the optical lens 141 and the sample 16 is shortened, the optical lens 141 also functions as a charge control electrode. That is, a transparent conductive film 17b is deposited on the optical lens 141, and a voltage can be applied by the control device 30 while transmitting the probe light 26, the pump light 27, and the signal light 28. As a material of the transparent conductive film 17b, ITO, ITZO, or the like may be used, or a metal thin film made of aluminum, gold, or the like may be used. Instead of depositing the film on the optical lens 141, the charge control electrode may be a transparent electrode and may be disposed below the optical lens 141 separately from the optical lens 141. The probe light 26 and the pump light 27 are integrated on the same optical path using a dichroic mirror 142 having different transmission-reflection characteristics depending on a wavelength of the light. The signal light 28 propagates in a reverse direction along the optical path of the probe light 26, is reflected by a beam splitter 143, passes through the optical filter 23, and is detected by the photodetection system 24. In this way, in the inspection device 4, the probe light 26 is focused on the sample 16 by the optical lens 141, whereby the film quality measurement can be performed with high space resolution. Since the optical lens 141 is disposed in the vicinity of the sample 16, there is also an advantage of improving a detection rate for scattered light and emitted light from the sample 16. FIG. 14 shows only typical optical components constituting the optical system, and general elements such as lenses and mirrors are omitted.

The invention has been described above by way of embodiments and modifications. The embodiments and modifications described above can be variously modified without departing from the gist of the invention, and can also be used in combination.

### REFERENCE SIGNS LIST

1, 2, 3, 4: inspection device
10: sample chamber
11: lens barrel
12: charged particle source
13: charged particle beam
14: blanker
15: viewport
16: sample
17: charge control electrode
17b: transparent conductive film
21: first light source
22: second light source
23: optical filter
24: photodetection system
25: signal processing device
26: probe light
27: pump light
28: signal light
30: control device
31: computer
41, 51: database
60: wafer heat map
61: wafer
62: chip section
70: setting-measurement screen
71: setting file selection section
72: setting tab
73: laser modulation tab
74: sequence diagram
75: electron beam condition setting section
76: charge control electrode condition setting section
77: laser condition setting section
78: sweep range setting section
79: save button
81: measurement tab
82: inspection chip section setting section
83: inspection execution button
84: wafer heat map display section
85: save button
90: result output screen
91: result file selection section
92: wafer heat map display section
93: histogram display section
94: inspection chip section measurement result display section
100: signal electron
101: energy filter
102: signal electron detector
103, 104, 105: signal electron spectrum
110: surface electrometer
120: partition wall
131: third light source
132: fourth light source
133: first excitation light
134: second excitation light
135: first photoelectron
136: second photoelectron
141: optical lens
142: dichroic mirror
143: beam splitter

1. An inspection device for inspecting a film quality of a film formed on a sample, the inspection device comprising:
a charged particle source configured to irradiate the sample with a charged particle beam;
a first light source configured to irradiate the sample with first light;
a photodetection system configured to detect signal light generated when the sample is irradiated with the first light;
a charge control electrode configured to control an electric field on the sample or a second light source configured to irradiate the sample with second light;
a control device configured to modulate an electronic state of the sample using the charged particle source and the charge control electrode or the second light source; and
a computer configured to estimate the film quality of the film formed on the sample based on a detection signal of the signal light modulated according to the modulated electronic state of the sample, the detection signal being output from the photodetection system.

2. The inspection device according to claim 1, comprising:
both the charge control electrode and the second light source, wherein
the control device modulates the electronic state of the sample using at least one of the charged particle source, the charge control electrode, and the second light source.

3. The inspection device according to claim 2, wherein
the photodetection system outputs the detection signal indicating a change in the signal light due to the modulated electronic state of the sample.

4. The inspection device according to claim 3, wherein
the detection signal is expressed as a model formula including a plurality of fit parameters, and
the computer includes a database in which film quality information on a combination of the plurality of fit parameters is registered, calculates the plurality of fit parameters of the detection signal by fitting the detection signal to the model formula, and collates the plurality of calculated fit parameters with the database.

5. The inspection device according to claim 3, wherein
the control device modulates the second light source while changing an electric field intensity applied to the sample by the charge control electrode.

6. The inspection device according to claim 5, wherein
the detection signal has dependency on the electric field intensity applied to the sample, and
the computer includes a database in which film quality information on a feature indicating the dependency is registered, calculates the feature indicating the dependency based on the detection signal, and collates the calculated feature indicating the dependency with the database.

7. The inspection device according to claim 6, further comprising:
a signal electron detector configured to detect signal electrons generated when the sample is irradiated with the charged particle beam, wherein
the computer calculates a surface voltage of the sample based on energy of the signal electrons detected by the signal electron detector.

8. The inspection device according to claim 6, further comprising:
a surface electrometer configured to measure a surface voltage of the sample.

9. The inspection device according to claim 1, wherein
the sample is disposed in the atmosphere,
the charged particle source is disposed in a lens barrel including a partition wall for maintaining the charged particle source in a vacuum atmosphere, and
the charged particle beam penetrates the partition wall, and the sample is irradiated with the charged particle beam.

10. The inspection device according to claim 1, wherein
the sample and the charged particle source are disposed in the atmosphere, and
the charged particle source is an electrode that generates ions by corona discharge.

11. The inspection device according to claim 1, wherein
the sample is irradiated with the first light from a direction perpendicular to the film formed on the sample, and
the sample is irradiated with the charged particle beam obliquely with respect to the film formed on the sample.

12. The inspection device according to claim 11, further comprising:
an optical lens configured to focus the first light, wherein
a conductive film serving as the charge control electrode is formed on a surface of the optical lens on a sample side.

13. The inspection device according to claim 11, further comprising:
an optical lens configured to focus the first light, wherein
the charge control electrode is a transparent electrode disposed between the optical lens and the sample.

14. An inspection device for inspecting a film quality of a film formed on a sample, the inspection device comprising:
a first light source configured to irradiate the sample with first light;
a photodetection system configured to detect signal light generated when the sample is irradiated with the first light;
a charge control electrode configured to control an electric field on the sample;
a third light source configured to irradiate the charge control electrode with third light to generate photoelectrons;
a fourth light source configured to irradiate the sample with fourth light to generate photoelectrons;
a control device configured to control a voltage applied to the charge control electrode, the third light source, and the fourth light source to modulate an electronic state of the sample; and
a computer configured to estimate the film quality of the film formed on the sample based on a detection signal of the signal light modulated according to the modulated electronic state of the sample, the detection signal being output from the photodetection system.

15. A film quality inspection method for inspecting a film quality of a film formed on a sample, the film quality inspection method comprising:
irradiating the sample with a charged particle beam to charge the sample;
irradiating the sample with probe light in a state in which an electronic state of the sample is modulated;
detecting signal light generated when the sample is irradiated with the probe light; and
estimating the film quality of the film formed on the sample based on a detection signal of the signal light modulated according to the modulated electronic state of the sample.

16. The film quality inspection method according to claim 15, wherein
the sample is irradiated with the probe light in a state in which the electronic state of the sample is modulated, while changing an electric field intensity applied to the sample, and
the film quality of the film formed on the sample is estimated based on electric field intensity dependency of the detection signal of the signal light modulated according to the modulated electronic state of the sample.
